(19) United States
(12) Patent Application Publication
(10) Pub. No.: US 2026/0314145 A1
(43) Pub. Date: Oct. 8, 2026

(54) WIRING SUBSTRATE, TRANSPARENT DISPLAY SUBSTRATE, AND TILED SCREEN

(71) Applicants: Hefei BOE Ruisheng Technology Co., Ltd., Hefei, Anhui (CN); BOE Technology Group Co., Ltd., Beijing (CN)

(72) Inventors: Tingwei HAN, Beijing (CN); Zouming XU, Beijing (CN); Jie WANG, Beijing (CN); Xintao WU, Beijing (CN); Jiawei XU, Beijing (CN); Ningyu LUO, Beijing (CN); Wenzhuo TANG, Beijing (CN)

(21) Appl. No.: 19/482,309

(22) PCT Filed: Apr. 22, 2024
(86) PCT No.: PCT/CN2024/089174

§ 371 Date: Nov. 7, 2025

(30) Foreign Application Priority Data
May 25, 2023 (CN) 202310620018.0

(51) Int. Cl. H10H 29/49; H10H 29/01

(52) U.S. Cl. CPC H10H 29/49; H10H 29/012

(57) ABSTRACT

A wiring substrate, a transparent display substrate, and a tiled screen are disclosed. The wiring substrate includes: a transparent substrate including a first surface and a second surface opposite to each other, the second surface includes a wiring region and a bonding region arranged along a first direction, and a plurality of connecting through holes are arranged in the wiring region; a plurality of first-type wires located on the first surface of the transparent substrate and in one-to-one correspondence with the plurality of connecting through holes, the plurality of first-type wires are arranged at intervals along the first direction, each of the plurality of first-type wires extends along a second direction, and the first direction is perpendicular to the second direction; and a plurality of second-type wires located on the second surface of the transparent substrate and in one-to-one correspondence with the plurality of first-type wires.

### CROSS-REFERENCE TO RELATED APPLICATION

This application is a National Stage of International Application No. PCT/CN2024/089174, filed on Apr. 22, 2024, which claims priority to Chinese Patent Applications No. 202310620018.0, filed with the China National Intellectual Property Administration on May 25, 2023, and entitled “Wiring Substrate, Transparent Display Substrate, and Tiled Screen”, the content of which is hereby incorporated by reference in its entirety.

### TECHNICAL FIELD

The present application relates to the technical field of display apparatus, and particularly to a wiring substrate, a transparent display substrate, and a tiled screen.

### BACKGROUND

In recent years, advantages of glass transparent substrate have been gradually highlighted in the field of new display technology. The glass transparent substrate is more thermally conductive than a transparent substrate of printed circuit board (PCB) material, and the service life of the glass transparent substrate is not reduced due to increase of a quantity of light-emitting diode LED chips. The glass transparent substrate has characteristics of good flatness, low expansion and contraction coefficient and the like.

When a backlight is highly finely partitioned, a glass substrate can realize a narrow bezel and a low OD value (a distance between a lower surface of a diffusion sheet and an upper surface of a circuit board), so that a television can be made lighter and more fashionable. The glass transparent substrate can make an area of a backplane larger as required, to realize infinite splicing and relatively lower cost.

Transparency of the glass transparent substrate is also advantageous in the field of direct display. An image can be displayed on the glass transparent substrate used as a display window. Human eyes can not only see an internal object through the glass transparent substrate, but also see the image displayed.

Glass-based transparent display panels need to be spliced, and uniformity of wiring is very important. When the panel is in a dark state (not lit), it is easy to see copper wiring on the surface, and the image has a grid feeling. Therefore, how to evenly arrange internal wiring of the display panel to improve the dark image and splicing effect of the panel is particularly important.

### SUMMARY

The present application provides a wiring substrate, a transparent display substrate, and a tiled screen, the wiring substrate can eliminate uneven grid feeling of the tiled screen in a dark state, achieve a transparent display tiled effect with even wiring, so that a visual effect of the tiled screen is better.

In order to achieve the above purpose, the present application provides following technical schemes.

A wiring substrate, including:
a transparent substrate, including a first surface and a second surface opposite to each other, where the second surface includes a wiring region and a bonding region arranged along a first direction, and a plurality of connecting through holes are arranged in the wiring region;
a plurality of first-type wires, located on the first surface of the transparent substrate and in one-to-one correspondence with the plurality of connecting through holes, where the plurality of first-type wires are arranged at intervals along the first direction, each of the plurality of first-type wires extends along a second direction, and the first direction is perpendicular to the second direction; and
a plurality of second-type wires, located on the second surface of the transparent substrate and in one-to-one correspondence with the plurality of first-type wires, where the plurality of second-type wires are arranged at intervals along the second direction, each of the plurality of second-type wires extends along the first direction, and each of the first-type wires is connected with a corresponding one of the second-type wires at a corresponding one of the connecting though holes.

Optionally, the plurality of first-type wires are sequentially divided into M first wire groups along the first direction, a quantity of the first-type wires in each of the first wire groups is p, and M and p are integers greater than 0;
the plurality of second-type wires are sequentially divided into M second wire groups along the second direction, the M second wire groups are in one-to-one correspondence with the M first wire groups, a quantity of the second-type wires in each of the second wire groups is p, and p first-type wires in each of the first wire groups are connected with p second-type wires in a corresponding one of the second wire groups in one-to-one correspondence.

Optionally, a distance between every adjacent two of the first wire groups is equal, and a distance between every adjacent two of the first-type wires in each of the first wire groups is equal;
a distance between every adjacent two of the second wire groups is equal, and a distance between every adjacent two of the second-type wires in each of the second wire groups is equal.

Optionally, along the second direction, a distance between any adjacent two of the second-type wires in an i^{th} second wire group is a first preset distance, i is an integer greater than 1 and less than M; a distance between any adjacent two of the second-type wires in a 1^{st} second wire group is a second preset distance, and a distance between any adjacent two of the second-type wires in an M^{th} second wire group is a third preset distance;
the second preset distance and/or the third preset distance is less than the first preset distance.

Optionally, the plurality of connecting through holes corresponding to the plurality of first-type wires in each of the first wire groups are sequentially arranged along a third direction, the third direction has an included angle with the first direction and/or the second direction.

Optionally, the wiring substrate further includes a plurality of connecting parts, where the plurality of connecting parts are filled in the plurality of connecting through holes in one-to-one correspondence, and the first-type wires are connected with the second-type wires through the connecting parts in the connecting through holes.

Optionally, the wiring substrate further includes a first insulating layer, a bonding metal layer and a second insulating layer;
where the first insulating layer is at a side of the plurality of first-type wires away from the transparent substrate;
the bonding metal layer is at a side of the insulating layer away from the transparent substrate, the bonding metal layer includes a plurality of pad parts arranged at intervals in an array, and the plurality of pad parts are arranged in M rows along the first direction and arranged in M columns along the second direction;
the second insulating layer is at a side of the bonding metal layer away from the first insulating layer, the second insulating layer includes bonding hole groups in one-to-one correspondence with the plurality of pad parts;
where a distance between centers of every adjacent two of the pad parts along the second direction is equal;
each row of the pad parts is opposite to a position of a corresponding one of the first wire groups, and each column of the pad parts is opposite to a position of a corresponding one of the second wire groups.

Optionally, along the second direction, an orthographic projection of a j^{th} column of the pad parts on the transparent substrate and an orthographic projection of the second wire group corresponding to the j^{th} column of the pad parts on the transparent substrate have a first relative positional relationship, where j is an integer greater than 1 and less than M; an orthographic projection of a first column of the pad parts on the transparent substrate and an orthographic projection of the second wire group corresponding to the first column of the pad parts on the transparent substrate have a second relative positional relationship; an orthographic projection of an M^{th} column of the pad parts on the transparent substrate and an orthographic projection of the second wire group corresponding to the M^{th} column of the pad parts on the transparent substrate have a third relative positional relationship, the first relative positional relationship is different from the second relative positional relationship, and/or the first relative positional relationship is different from the third relative positional relationship

Optionally, the p second-type wires in the second wire group include a first power line, a second power line, a ground line, a data line and a transfer line sequentially arranged along the second direction;
the pad part includes a plurality of first pad groups and a second pad group arranged at intervals along the second direction, the plurality of first pad groups are arranged at intervals along the first direction;
in the j^{th} column of the pad parts, an orthographic projection of the plurality of first pad groups on the transparent substrate is between an orthographic projection of the second power line on the transparent substrate and an orthographic projection of the ground line on the transparent substrate;
in the first column of the pad parts, an orthographic projection of the plurality of first pad groups on the transparent substrate and an orthographic projection of the second power line on the transparent substrate overlap;
in the M^{th} column of the pad parts, an orthographic projection of the plurality of first pad groups on the transparent substrate and an orthographic projection of the ground line on the transparent substrate overlap.

Optionally, an orthographic projection of each row of the pad parts on the transparent substrate is within an orthographic projection of the corresponding one of the first-type wires on the transparent substrate.

Optionally, along the first direction, one first-type wire in middle of the first-type wires in each of the first wire groups is a middle signal line; the orthographic projection of each row of the pad parts on the transparent substrate is within an orthographic projection of the middle signal line on the transparent substrate.

Optionally, the p first-type wires in the first wire group include an auxiliary transfer line, an auxiliary data line, an auxiliary ground line, an auxiliary second power line and an auxiliary first power line sequentially arranged along the first direction;
each of the first pad groups includes a first light-emitting pad and a second light-emitting pad arranged along the second direction, a part of first light-emitting pads in the plurality of first pad groups are connected with the auxiliary first power line and the other part of the first light-emitting pads are connected with the auxiliary second power line;
the second pad group includes a first column of pads and a second column of pads arranged along the second direction, the first column of pads includes a plurality of connecting pads connected with the second light-emitting pads in the plurality of first pad groups in one-to-one correspondence, the second column of pads includes a data signal pad, an address signal pad and a ground pad sequentially arranged, the data signal pad is connected with the auxiliary data line, and the ground pad is connected with the auxiliary ground line;
an orthographic projection of the pad part on the transparent substrate is within an orthographic projection of the auxiliary ground line on the transparent substrate.

Optionally, the bonding metal layer further includes M addressing signal lines extending along the first direction, the M addressing signal lines are in one-to-one correspondence with the M columns of pad parts, each of the addressing signal lines is connected with address signal pads of all of the pad parts of a corresponding column, and the M addressing signal lines are connected with M auxiliary transfer lines in one-to-one correspondence.

Optionally, an orthographic projection of the addressing signal line on the transparent substrate is within an orthographic projection of the second-type wire on the transparent substrate.

The present application further provides a transparent display substrate, including the wiring substrate according to any one of the above technical schemes, and further including a plurality of element groups;
where the plurality of element groups are in one-to-one correspondence with the plurality of pad parts on the wiring substrate, each of the element groups is connected with a corresponding one of the pad parts through a bonding hole group on the wiring substrate.

The present application further provides a tiled screen, including at least two transparent display substrates each according to any one of the above technical schemes.

Embodiments of the present application provide a wiring substrate, a transparent display substrate, and a tiled screen. In the wiring substrate, the bonding region for bonding the driving integrated circuit can be arranged on the second surface, and wires are arranged on both sides of transparent substrate. The plurality of second-type wires on the second surface of the transparent substrate extend along the first direction, and may be connected with the driving integrated circuit located in the bonding region. The plurality of first-type wires on the first surface of the transparent substrate extend along the second direction. Each of the first-type wires is connected with a corresponding second-type wire through a connecting through hole in the transparent substrate. The plurality of first-type wires may be used to be connected with a plurality of pad parts arranged in an array on the first surface of the transparent substrate. Since the plurality of pad parts are directly connected with the plurality of first type wires, if it is desired to reduce the distance of the edge of the transparent substrate from the adjacent column of the pad parts along the second direction, a position of the pad part has no limitation to positions of the plurality of second-type wires on the second surface of the transparent substrate. The plurality of second-type wires may be uniformly wired on the second surface. Meanwhile, the plurality of first-type wires extend along the second direction, the second direction is perpendicular to the first direction, reduction of the distance of the edge of the transparent substrate from the adjacent column of pad parts along the second direction has no effect on the arrangement of the first-type wires. The plurality of first-type wires may also be uniformly wired on the first surface. Therefore, through wires arranged on both sides of transparent substrate, the wiring substrate can not only realize the narrow bezel design of the left and right bezels, but also can realize uniform wiring on the transparent substrate, which is favorable for at least two transparent display substrates to be spliced along the second direction to form a tiled screen, so that a distance between spliced seams can be flexibly adjusted, and the uneven grid feeling of the tiled screen at a spliced position under a dark state is eliminated, achieving a transparent display tiled effect with uniform wiring, and a visual effect of the tiled screen is better.

### BRIEF DESCRIPTION OF FIGURES

FIG. 1 is a sectional view of a wiring substrate in related art;

FIG. 2 is a schematic diagram of circuit connection of a wiring substrate in the related art;

FIG. 3 is a schematic plan view of a wiring substrate in the related art;

FIG. 4 is a schematic structural diagram of a splicing part of a wiring substrate in the related art;

FIG. 5 and FIG. 6 are schematic plan views of another wiring substrate in the related art;

FIG. 7 is a schematic plan view of a wiring substrate according to an embodiment of the present application;

FIG. 8 is a sectional view of a wiring substrate according to an embodiment of the present application;

FIG. 9 and FIG. 10 are schematic plan views of another wiring substrate according to embodiments of the present application;

FIG. 11 is a schematic plan view of another wiring substrate according to an embodiment of the present application;

FIG. 12 is a sectional view of a wiring substrate according to an embodiment of the present application;

FIG. 13 is a schematic structural diagram of a pad part according to an embodiment of the present application;

FIG. 14 and FIG. 15 are schematic plan views of another wiring substrate according to embodiments of the present application;

FIG. 16 to FIG. 19 are schematic diagrams of a manufacturing process of a wiring substrate according to embodiments of the present application.

### REFERENCE NUMERALS

01—transparent substrate; 02—first metal layer; 021—wire group; 0211—signal line; 03—first insulating layer; 04—bonding metal layer; 041—pad part; 0411—first pad group; 0412—second pad group; 05—second insulating layer; 1—transparent substrate; 11—connection through hole; 2—first wire group; 21—first-type wire; 3—second wire group; 31—second-type wire; 4—connecting part; 5—first insulating layer; 6—bonding metal layer; 61—pad part; 611—first pad group; 612—second pad group; 62—connecting wire; 7—second insulating layer; 71—bonding hole; 81—first buffer layer; 82—second buffer layer; 9—third insulating layer.

### DETAILED DESCRIPTION

Technical solutions of embodiments of the present disclosure will be clearly and completely described below in conjunction with accompanying drawings in embodiments of the present disclosure. Apparently, embodiments described are some rather than all of embodiments of the present disclosure. Embodiments in the present disclosure and features of embodiments may be combined with each other without conflict. Based on embodiments of the present disclosure, all other embodiments obtained by those of ordinary skill in the art without making creative efforts fall within the scope of protection of the present disclosure.

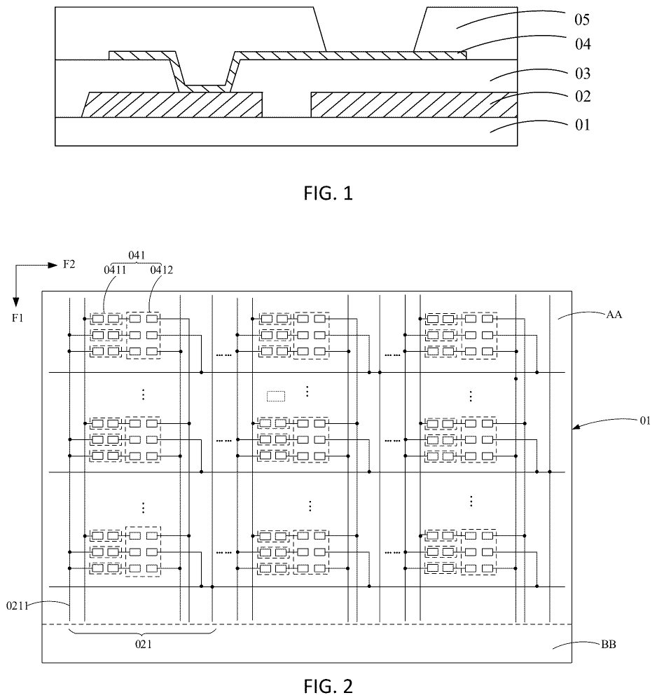

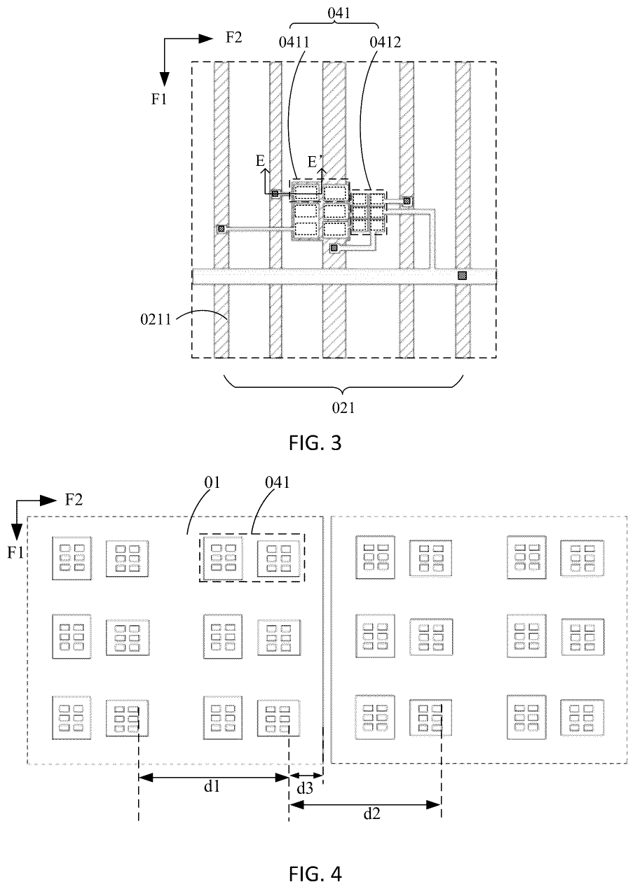

In the related art, transparency of a glass transparent substrate is advantageous in the field of direct display. A display element arranged on the glass transparent substrate may constitute a transparent display substrate. The transparent display substrate can be used as a display window. Human eyes can not only see an internal object through the transparent display substrate, but also see an image displayed on the transparent display substrate. As shown in FIG. 1, the transparent display substrate may include a wiring substrate, and a plurality of element groups and a driving integrated circuit bound on the wiring substrate. The wiring substrate may include a transparent substrate 01, and a first metal layer 02, a first insulating layer 03, a bonding metal layer 04 and a second insulating layer 05 stacked sequentially on a first surface of the transparent substrate. FIG. 2 is a schematic diagram of circuit connection of a wiring substrate. FIG. 3 is a schematic diagram of a connection structure of a wire group and a pad part 041. FIG. 1 is a sectional view at EE′ in FIG. 3. A first surface of the transparent substrate 01 has a wiring region AA and a bonding region BB arranged along a first direction F1. The transparent substrate may be a glass transparent substrate. The first metal layer 02 includes n wire groups 021 located in the wiring region AA and arranged along a second direction F2. The second direction F2 is perpendicular to the first direction F1. Each of the wire groups 021 includes a plurality of signal lines 0211 extending along the first direction F1. The bonding metal layer 04 includes a plurality of pad parts 041 located in the wiring region AA and distributed in an m*n array, where m and n are integers greater than 0. The plurality of pad parts are arranged in m rows along the first direction F1 and in n columns along the second direction F2. One of the wire groups 021 is correspondingly connected with one column of the pad parts 041. Each pad part 041 includes a plurality of first pad groups 0411 and a second pad group 0412 arranged along the second direction F2. In the transparent display substrate, the plurality of element groups are located at a side of the second insulating layer 05 of the wiring substrate away from the bonding metal layer 04 and are in one-to-one correspondence with the plurality of pad parts 041. Each of the element groups includes a plurality of light-emitting diode chips and a driving chip. The plurality of light-emitting diode chips are connected with the plurality of first pad groups 0411 in a corresponding pad part 041 in one-to-one correspondence. The driving chip is connected with the second pad group 0412 in the corresponding pad part 041. The driving integrated circuit is located in the bonding region of the transparent substrate and is connected with the n wire groups.

Since the wiring substrate has signal lines, pad parts and the like, when the transparent display substrate is in a dark state, the viewer can visually experience a grid feeling when viewing a display window. In order to optimize the visual effect of the transparent display substrate in the dark state and eliminate the uneven grid feeling, as shown in FIG. 3, following can be set: (1) a distance between every two adjacent wire groups is close; (2) a distance between every two adjacent signal lines in each wire group is close; (3) a distance between centers of every two adjacent pad parts is close; (4) an orthographic projection of the first pad group on the transparent substrate is within an orthographic projection of a signal line in the middle of a wire group on the transparent substrate.

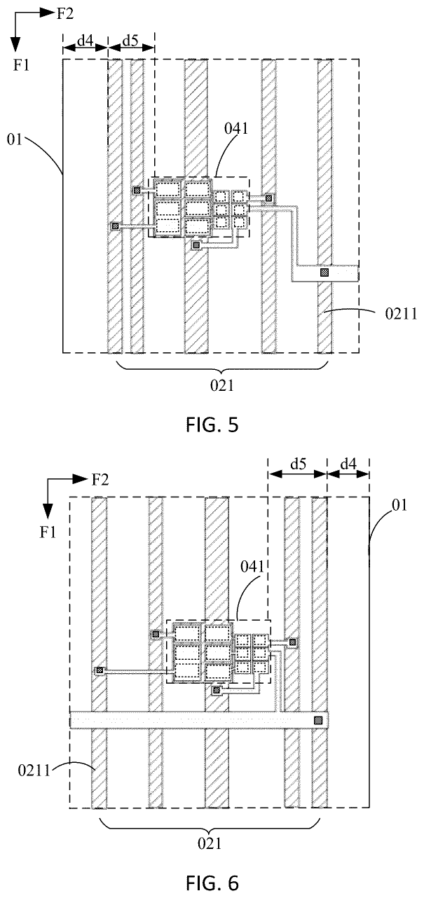

When a plurality of transparent display substrates are spliced to form a large-size display screen, a size of a seam between the transparent display substrates can affect the visual effect. At least two transparent display substrates can be spliced along an arrangement direction of the wire groups. FIG. 4 is a schematic diagram of splicing of wiring substrates corresponding to two transparent display substrates arranged side by side. Where d1 is a distance between two adjacent columns of pad parts on a wiring substrate, d2 is a distance between two adjacent columns of pad parts at a joint of two wiring substrates, d3 is a distance between a pad part closest to a splice side of a wiring substrate and the splice side. In order to achieve a better visual effect of splicing, d1 should be made equal to d2. In a process of splicing two wiring substrates, if d1 is greater than 2.d3, the two wiring substrates to be spliced can be separated by a certain distance, that is, the distance between the two wiring substrates is increased. However, if d1 is smaller, in order to achieve a desired splicing effect, a side of the wiring substrate for splicing is narrower, that is, the distance d3 between the pad part closest to the splice side of the wiring substrate and the splice side needs to be reduced. As shown in FIG. 5 and FIG. 6, FIG. 5 is a schematic structural diagram of connection between the first column of pad parts along the second direction F2 and a wire group. FIG. 6 is a schematic structural diagram of connection between the n^{th} column of pad parts along the second direction F2 and a wire group. A distance between a wire closest to an edge of the wiring substrate and the edge of the wiring substrate is d4. A distance between the wire closest to the edge of the wiring substrate and the pad part closest to the edge of the wiring substrate is d5, and d3 may be equal to d4+d5. In a process of manufacturing the wiring substrate, because a material of the transparent substrate is glass, the edge of the transparent substrate is easily damaged by external force such as collision and the like. In this case, if the wire is too close to the edge, damage to the edge can also affect reliability of an electrical structure (pad part or wire). In order to ensure the reliability of the wire, the distance between the edge of the transparent substrate and the wire should be at least 0.5 mm. Therefore, when d3 needs to be reduced to ensure that d1 is equal to d2, it is not easy to change by reducing d4. In this case, d5 needs to be reduced. It can be seen from FIG. 5 and FIG. 6 that reduction of d5 may cause wiring of some signal lines 0211 in the wire group 021 adjacent to the edge to be crowded, and it cannot be ensured that all signal lines in the wire group are uniformly arranged. When the transparent display substrate is in a dark state, the splicing part of the transparent display substrate is easy to cause uneven grid feeling visually, affecting a visual effect of a tiled screen.

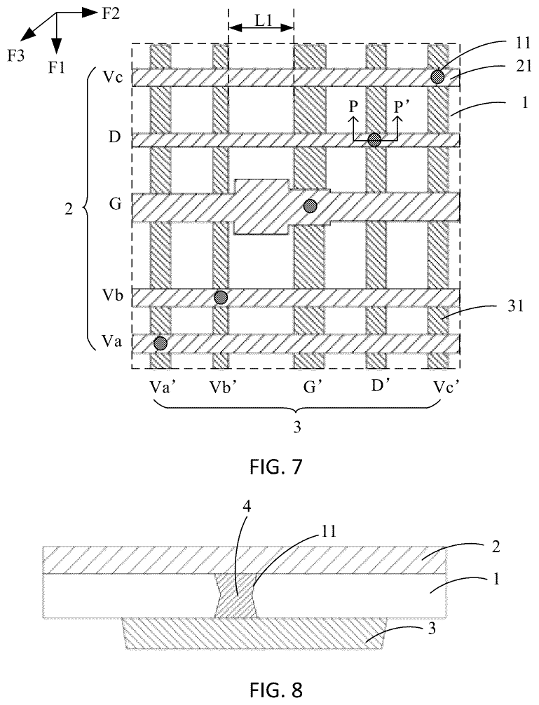

In order to address the above technical problem, the present application provides a wiring substrate. FIG. 7 is a schematic plan view of a wiring substrate according to an embodiment of the present application. FIG. 8 is a sectional view at PP′ in FIG. 7. The wiring substrate includes following components.

A transparent substrate 1 includes a first surface and a second surface opposite to each other. The second surface includes a wiring region and a bonding region arranged along a first direction F1, and a plurality of connecting through holes 11 are arranged in the wiring region.

A plurality of first-type wires 21 are located on the first surface of the transparent substrate 1 and in one-to-one correspondence with the connecting through holes 11. The plurality of first-type wires 21 are arranged at intervals along the first direction F1, and each of the plurality of first-type wires 21 extends along a second direction F2. The first direction F1 is perpendicular to the second direction F2.

A plurality of second-type wires 31 are located on the second surface of the transparent substrate 1 and in one-to-one correspondence with the plurality of first-type wires. The plurality of second-type wires 31 are arranged at intervals along the second direction F2. Each of the second-type wires 31 extends along the first direction F1. Each of the first-type wires 21 is connected with a corresponding second-type wire 31 at a corresponding connection though hole 11.

In the wiring substrate according to an embodiment of the present application, the bonding region for bonding the driving integrated circuit can be arranged on the second surface, and wires are arranged on both sides of transparent substrate 1. The plurality of second-type wires 31 on the second surface of the transparent substrate 1 extend along the first direction F1, and may be connected with the driving integrated circuit located in the bonding region. The plurality of first-type wires 21 on the first surface of the transparent substrate 1 extend along the second direction F2. Each of the first-type wires 21 is connected with a corresponding second-type wire 31 through a connecting through hole 11 in the transparent substrate 1. The plurality of first-type wires 21 may be used to be connected with a plurality of pad parts arranged in an array on the first surface of the transparent substrate 1. Since the plurality of pad parts are directly connected with the plurality of first type wires 21, if it is desired to reduce the distance of the edge of the transparent substrate 1 from the adjacent column of the pad parts along the second direction F2, a position of the pad part has no limitation to positions of the plurality of second-type wires 31 on the second surface of the transparent substrate 1. The plurality of second-type wires 31 may be uniformly wired on the second surface. Meanwhile, the plurality of first-type wires 21 extend along the second direction F2, the second direction F2 is perpendicular to the first direction F1, reduction of the distance of the edge of the transparent substrate 1 from the adjacent column of pad parts along the second direction F2 has no effect on the arrangement of the first-type wires 21. The plurality of first-type wires 21 may also be uniformly wired on the first surface. Therefore, through wires arranged on both sides of transparent substrate, the wiring substrate can not only realize the narrow bezel design of the left and right bezels, but also can realize uniform wiring on the transparent substrate 1, which is favorable for at least two transparent display substrates to be spliced along the second direction F2 to form a tiled screen, so that a distance between spliced seams can be flexibly adjusted, and the uneven grid feeling of an image at a spliced position under a dark state is eliminated, achieving a better splicing visual effect.

It should be noted that uniform wiring means that the distance between any adjacent wires on the transparent substrate is approximately equal. That is, the difference in the distance between wires is small visually, which is beneficial to the transparent display effect of the transparent display substrate.

In addition, if the wiring substrate does not consider the transparency or the requirement for the transparency is small, a width of the second-type wire 31 on the second surface of the transparent substrate 1 can be increased, and a thickness of the second-type wire 31 can be reduced, to reduce a resistance of the wire. In this way, display brightness of the transparent display substrate can be improved, and a better visual effect is achieved.

In an embodiment of the present application, as shown in FIG. 7, the plurality of first-type wires 21 can be sequentially divided into M first wire groups 2 along the first direction F1. A quantity of the first-type wires 21 in each of the first wire groups 2 is p, M and p are integers greater than 0. The plurality of second-type wires 31 can be sequentially divided into M second wire groups 3 along the second direction F2, the M second wire groups are in one-to-one correspondence with the M first wire groups. A quantity of the second-type wires 31 in each of the second wire groups 3 is p, and p first-type wires in each of the first wire groups are connected with p second-type wires in a corresponding second wire group in one-to-one correspondence. The plurality of first-type wires 21 and the plurality of second-type wires 31 are sequentially arranged in groups, to facilitate connection of the second-type wires 31 on the second surface with the first-type wires 21 on the first surface, which is more beneficial to reasonable wiring of the wires on the transparent substrate 1.

A distance between every adjacent two of first wire groups 2 may be equal, and a distance between every adjacent two of the first-type wires 21 in each of the first wire groups 2 may be equal, to realize uniform wiring on the first surface of the transparent substrate 1, eliminate the uneven grid feeling in the dark state, and improve the visual effect of the transparent display substrate. Optionally, the distance between adjacent two of the first wire groups 2 may be equal to the distance between adjacent two of the first-type wires 21 in the first wire group 2, that is, the distance between every adjacent two of the first-type wires 21 may be equal, to better improve the visual effect of the transparent display substrate.

A distance between every adjacent two of the second wire groups 3 may be equal, and a distance between every adjacent two of the second-type wires 31 in each of the second wire groups 3 may be equal, to realize uniform wiring on the second surface of the transparent substrate 1, eliminate the uneven grid feeling in the dark state, and improve the visual effect of the transparent display substrate.

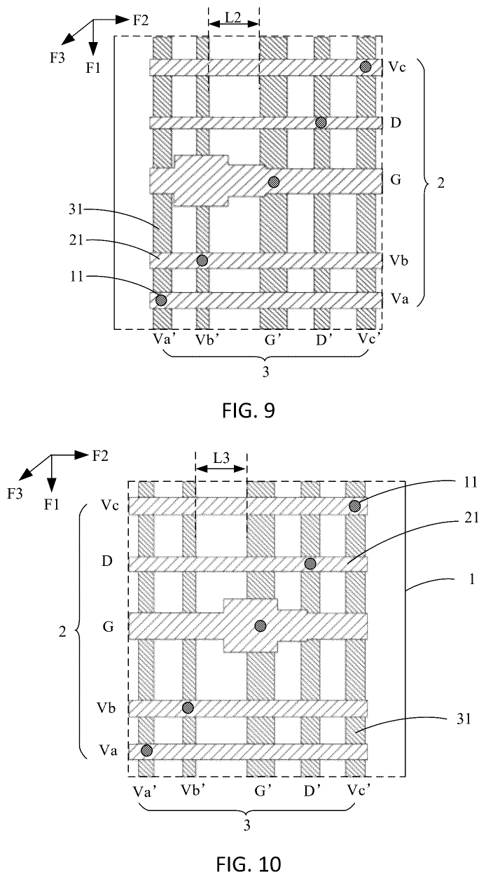

In an embodiment of the present application, as shown in FIG. 7, FIG. 7 is a schematic diagram of a connection structure of the i^{th} second wire group in the wiring substrate. Along the second direction F2, a distance between any adjacent two of the second-type wires 31 in the i^{th} second wire group may be a first preset distance L1, and i is an integer greater than 1 and less than M. As shown in FIG. 9, FIG. 9 is a schematic diagram of a connection structure of the 1st second wire group in the wiring substrate. A distance between any adjacent two of the second-type wires 31 in the 1^{st} second wire group is a second preset distance L2. As shown in FIG. 10, FIG. 10 is a schematic diagram of a connection structure of the M^{th} second wire group in the wiring substrate. A distance between any adjacent two of the second-type wires 31 in the M^{th} second wire group is a third preset distance L3. The second preset distance L2 and/or the third preset distance L3 may be less than the first preset distance L1.

Along the second direction F2, the 1^{st} second wire group and the M^{th} second wire group are adjacent to the edge of the transparent substrate 1, in order to realize the narrow bezel design of the left bezel and/or the right bezel of the transparent display substrate and the uniform wiring of the splicing part of the tiled screen, a size of the bezel that needs to be narrowed can be realized by shortening the distance between the second-type wires 31 in the whole second wire group, to avoid centralized distribution of part of wires in the second wire group. In this way, the distance between the second-type wires 31 in the 1^{st} second wire group and/or the distance between the second-type wires 31 in the M^{th} second wire group may be slightly less than the distance between the second-type wires 31 in the i^{th} second wire group, to not only realize the narrow bezel design of the left bezel and/or the right bezel, but also realize uniform distribution of the wires visually and improve the visual effect of the transparent display substrate.

In the wiring substrate, in the plurality of second wire groups between the 1^{st} second wire group and the M^{th} second wire group, a distance between every adjacent two of second-type wires 31 is equal, so that the uniform wiring on the transparent display substrate can be better realized.

In an embodiment of the present application, the plurality of connecting through holes 11 corresponding to the plurality of first-type wires 21 in each of the first wire groups 2 are sequentially arranged along a third direction F3. The third direction F3 has an included angle with the first direction F1 and/or the second direction F2. As shown in FIGS. 7, 9, and 10, hole positions of a plurality of connecting through holes 11 corresponding to a first wire group are arranged in an oblique line, to realize uniformity of electrical signals on the plurality of first-type wires 21 and the plurality of second-type wires 31.

As shown in FIG. 8, the wiring substrate further includes a plurality of connecting parts 4. The plurality of connecting parts 4 are filled in the plurality of connecting through holes 11 in one-to-one correspondence. The first first-type wires 21 are connected with the second-type wires 31 through the connecting parts 4 in the connecting through holes 11. In a process of manufacturing the wiring substrate, after a plurality of connecting through holes 11 are formed in the transparent substrate 1, the connecting parts 4 may be formed in the connecting through holes 11 first. Then, the first-type wires 21 and the second-type wires 31 connected by the connecting parts 4 are formed on the first surface and the second surface of the transparent substrate 1 respectively, to avoid influence of the connecting through holes 11 on the subsequent wiring.

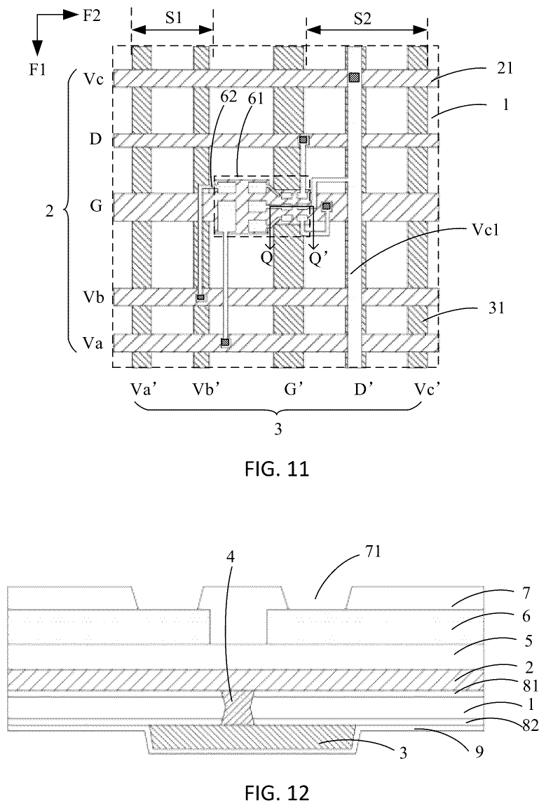

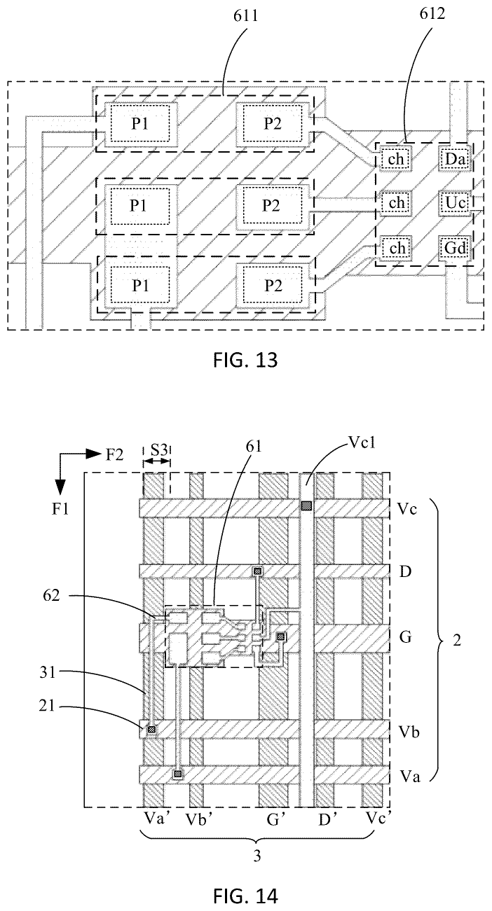

In an embodiment of the present application, the wiring substrate further includes a first insulating layer 5, a bonding metal layer 6, and a second insulating layer. As shown in FIGS. 11, 12 and 13, FIG. 11 is a schematic plan view of a transparent display substrate according to an embodiment of the present application. FIG. 12 is a sectional view at QQ′ in FIG. 11. FIG. 13 is an enlarged view of a pad part in FIG. 11. The first insulating layer 5 is located at a side of the plurality of first-type wires 21 away from the transparent substrate 1. The bonding metal layer 6 is located at a side of the insulating layer away from the transparent substrate 1. The bonding metal layer includes a plurality of pad parts 61 arranged at intervals in an array. The plurality of pad parts 61 are arranged in M rows along the first direction F1 and arranged in M columns along the second direction F2. Each of the pad parts 61 may include a plurality of pads. The second insulating layer 7 is located at a side of the bonding metal layer 6 away from the first insulating layer 5. The second insulating layer 7 includes bonding hole groups in one-to-one correspondence with the plurality of pad parts 61. Each of the bonding hole groups may include a plurality of bonding holes 71 for defining a plurality of pads in the pad part 61 in the bonding metal layer 6. A distance between centers of every adjacent two of the pad parts 61 along the second direction F2 is equal. Each row of the pad parts 61 is opposite to a position of one of the first wire groups 2, and each column of the pad parts 61 is opposite to a position of one of the second wire groups 3. That is, the M rows of pad parts are in one-to-one correspondence with positions of the M first wire groups, and the M columns of pad parts are in one-to-one correspondence with positions of the M second wire groups, so that arrangement of the subsequent element groups bonded to the pad parts 61 is uniform, and the transparent display effect of the transparent display substrate is improved.

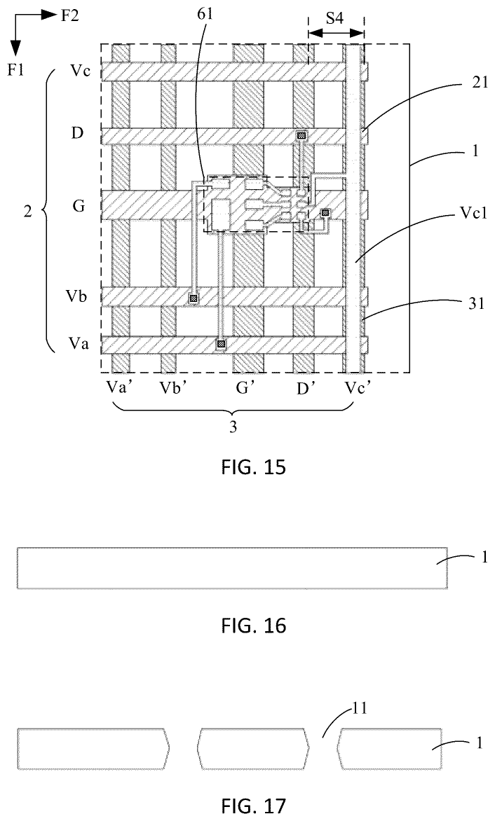

As shown in FIG. 11, FIG. 11 is a schematic view of a connection structure of the j^{th} column of the pad parts in the wiring substrate. Along the second direction, an orthographic projection of the j^{th} column of the pad parts on the transparent substrate 1 and an orthographic projection of the second wire group corresponding to the j^{th} column of the pad parts on the transparent substrate 1 have a first relative positional relationship, where j is an integer greater than 1 and less than M. FIG. 14 is a schematic view of a connection structure of a first row of pad parts in a wiring substrate. An orthographic projection of the first column of the pad parts on the transparent substrate 1 and an orthographic projection of the second wire group corresponding to the first column of the pad parts on the transparent substrate 1 have a second relative positional relationship. As shown in FIG. 15, FIG. 15 is a schematic view of a connection structure of the M^{th} column of the pad parts in the wiring substrate. An orthographic projection of the M^{th} column of the pad parts on the transparent substrate 1 and an orthographic projection of the second wire group corresponding to the M^{th} column of the pad parts on the transparent substrate 1 have a third relative positional relationship. In order to achieve a narrow bezel design, a distance between the second-type wires 31 in the second wire group corresponding to the first column of pad parts and/or a distance between the second-type wires 31 in the second wire group corresponding to the M^{th} column of pad parts may be slightly less than a distance between the second-type wires 31 in the second wire group corresponding to the j^{th} column of the pad parts. At this time, in order to ensure that a distance between centers of every adjacent two of the pad parts 61 along the second direction F2 is equal, there is a difference between the first relative positional relationship and the second relative positional relationship, and/or there is a difference between the first relative positional relationship and the third relative positional relationship.

For example, as shown in FIGS. 11, 14 and 15, the p second-type wires 31 in the second wire group 3 may include a first power line Va′, a second power line Vb′, a ground line G′, a data line D′ and a transfer line Vc′ sequentially arranged along the second direction F2.

As shown in FIG. 13, the pad part 61 may include a plurality of first pad groups 611 and a second pad group 612 arranged at intervals along the second direction F2. The plurality of first pad groups 611 are arranged at intervals along the first direction F1. As shown in FIG. 11, in the j^{th} column of the pad parts, an orthographic projection of the plurality of first pad groups 611 on the transparent substrate 1 is located between an orthographic projection of the second power line Vb′ on the transparent substrate 1 and an orthographic projection of the ground line G′ on the transparent substrate 1. As shown in FIG. 14, in the first column of the pad parts, an orthographic projection of the plurality of first pad groups 611 on the transparent substrate 1 overlaps with an orthographic projection of the second power line Vb′ on the transparent substrate 1. As shown in FIG. 15, in the M^{th} column of the pad parts, an orthographic projection of the plurality of first pad groups 611 on the transparent substrate 1 overlaps with an orthographic projection of the ground line G′ on the transparent substrate 1.

In the wiring substrate, through different relative positional relationships between the first pad groups 611 in the j^{th} column of the pad parts, the first column of the pad parts, and the M^{th} column of the pad parts with the second power line Vb′ and the ground line G′ in the second wire group 3, the difference between the first relative positional relationship and the second relative positional relationship can be reflected, and the difference between that first relative positional relationship and the third relative positional relationship can be reflected. As shown in FIG. 11, in the second wire group corresponding to the j^{th} column of the pad parts, distances between the first power line Va′ and the transfer line Vc′ located at two sides along the second direction F2 and the center of the j^{th} column of the pad parts are S1 and S2 respectively. As shown in FIG. 14, in the second wire group corresponding to the first column of the pad parts, a distance between the first power line Va′ adjacent to the edge of the transparent substrate 1 and the center of the first column of the pad parts is S3. As shown in FIG. 15, in the second wire group corresponding to the the N^{th} column of the pad parts, a distance between the transfer line Vc′ adjacent to the edge of the transparent substrate 1 and the center of the M^{th} column of the pad parts is S4. S1 is greater than S3, S2 is greater than S4, and design of left and right narrow bezels can be realized.

In an embodiment of the present application, in order to improve the visual effect of the transparent display substrate, as shown in FIGS. 11, 14 and 15, an orthographic projection of each row of pad parts 61 on the transparent substrate 1 may be located within an orthographic projection of one of the first-type wires 21 on the transparent substrate 1. Shielding of the first-type wire 21 on the pad parts 61 can prevent the pad parts 61 from affecting the visual effect of the transparent display substrate, a transparent area between wires can be increased, and transparency of the transparent display substrate can be improved.

In the wiring substrate, along the first direction F1, one first-type wire 21 in middle of the first-type wires 21 in each of the first wire groups 2 is a middle signal line. An orthographic projection of each row of pad parts 61 on the transparent substrate 1 may be located within an orthographic projection of the middle signal line on the transparent substrate 1, so that the plurality of pad parts 61 can be reasonably and uniformly arranged on the transparent display substrate, which is convenient for the uniform arrangement of subsequent element groups. The difference in the quantity of the first-type wires 21 on two sides of the element group is avoided, and the visual effect of the transparent display substrate is improved.

In particular, the p first-type wires 21 in the first wire group 2 may include an auxiliary transfer line Vc and an auxiliary data line D, an auxiliary ground line G, an auxiliary second power line Vb and an auxiliary first power line Va sequentially arranged along the first direction F1. The auxiliary data line D is connected with the data line D′ through a connecting through hole 11. The auxiliary transfer line Vc is connected with the transfer line Vc′ through a connecting through hole 11. The auxiliary ground line G is connected with the ground line G′ through a connecting through hole 11. The auxiliary second power line Vb is connected with the second power line Vb′ through a connecting through hole 11. The auxiliary first power line Va is connected with the first power line Va′ through a connecting through hole 11.

As shown in FIG. 13, each of the first pad groups 611 has a first light-emitting pad P1 and a second light-emitting pad P2 arranged along the second direction F2. A part of first light-emitting pads P1 in the plurality of first pad groups 611 are connected with the auxiliary first power line Va and the other part of the first light-emitting pads are connected with the auxiliary second power line Vb. The second pad group 612 has a first column of pads and a second column of pads arranged along the second direction F2. The first column of pads includes a plurality of connecting pads ch connected with the second light-emitting pads P2 in the plurality of first pad groups 611 in one-to-one correspondence. The second column of pads includes a data signal pad Da, an address signal pad Uc and a ground pad Gd sequentially arranged. The data signal pad Da is connected with the auxiliary data line D, and the ground pad Gd is connected with the auxiliary ground line G. An orthographic projection of the pad part 61 on the transparent substrate 1 may be located within an orthographic projection of the auxiliary ground line G on the transparent substrate 1. The plurality of pad parts 61 can be reasonably and uniformly arranged on the transparent display substrate, and the visual effect of the transparent display substrate is improved.

The bonding metal layer 6 further includes a plurality of connecting wires 62 for connecting to the pad parts 61. As shown in FIG. 11, the pad part 61 may include three first pad groups 611 arranged along the first direction F1. The first light-emitting pad P1 in one of the first pad groups 611 may be connected with the auxiliary second power line Vb through one of the connecting wires. The first light-emitting pads P1 in the other two of the first pad groups 611 may be connected with the auxiliary first power line Va through connecting wires. The second light-emitting pads P2 in the three first pad groups 611 are respectively correspondingly connected with three connecting pads ch in the second pad group 612 through the connecting wires. The data signal pad Da in the second pad group 612 is connected with the auxiliary data line D through a connecting wire. The ground pad Gd is connected with the auxiliary ground line G through a connecting wire. An orthographic projection of at least part of the connecting wires on the transparent substrate 1 may overlap with an orthographic projection of the plurality of second-type wires 31 on the transparent substrate 1, to alleviate the uneven grid feeling of the transparent display substrate in a dark state.

In an embodiment of the present application, the bonding metal layer 6 may further include at least one third-type wire extending along the first direction F1. An orthographic projection of the third-type wire on the transparent substrate 1 may be located within an orthographic projection of the first-type wire 21 on the transparent substrate 1, so that the transparent display substrate can be uniformly wired, and the visual effect of the transparent display substrate is improved.

For example, the third-type wire may be an addressing signal line. The bonding metal layer 6 further includes M addressing signal lines Vc1 extending along the first direction F1. The M addressing signal lines are in one-to-one correspondence with the M columns of pad parts. Each of the addressing signal lines Vc1 is connected with address signal pads Uc of all the pad parts 61 of a corresponding column. The M addressing signal lines are connected with the M auxiliary transfer lines in one-to-one correspondence. The address signal pads in the second pad group 612 may be connected with the addressing signal lines in the same layer through the connecting wires.

An orthographic projection of the addressing signal line Vc1 on the transparent substrate 1 is located within an orthographic projection of the second-type wire 31 on the transparent substrate 1, so that the transparent display substrate can be uniformly wired, and the visual effect of the transparent display substrate is improved.

For example, as shown in FIG. 11, the orthographic projection of the addressing signal line Vc1, with which the j^{th} column of pad parts or the first column of pad parts is connected, on the transparent substrate 1 may be located within an orthographic projection of the data line D′ on the transparent substrate 1. As shown in FIG. 15, the orthographic projection of the addressing signal line Vc1, with which the N^{th} column of pad parts 61 is connected, on the transparent substrate 1 may be located on within an orthographic projection of the ground line G′ on the transparent substrate 1.

As shown in FIG. 12, the first insulating layer 5 in the wiring substrate may include a plurality of layers of an organic insulating layer and an inorganic insulating layer stacked, and the second insulating layer 7 may include a plurality of layers of an organic insulating layer and an inorganic insulating layer stacked, to protect the transparent display substrate. In addition, the wiring substrate further includes a first buffer layer 81 located between the transparent substrate 1 and the plurality of first-type wires 21, a second buffer layer 82 located between the transparent substrate 1 and the plurality of second-type wires 31, and a third insulating layer 9 located at a side of the plurality of second-type wires 31 away from the transparent substrate 1, to protect the transparent display substrate.

An embodiment of the present application further provides a transparent display substrate including any one of the wiring substrates provided by the above technical schemes, and further including a plurality of element groups. The plurality of element groups are in one-to-one correspondence with the plurality of pad parts on the wiring substrate. Each of the element groups is connected with a corresponding pad part through a bonding hole group on the wiring substrate.

In particular, the element group may include a plurality of light-emitting elements connected with the plurality of first pad groups 611 in the pad part 61 in one-to-one correspondence, and a driving element correspondingly connected with the second pad group 612 in the pad part 61. In practical applications, the light-emitting element may be a light-emitting diode chip, and the driving element may be a driving chip. As shown in FIG. 13, the pad part 61 may include three first pad groups 611, and the three first pad groups 611 are correspondingly connected with three light-emitting elements. The three light-emitting elements may be a red light-emitting element, a green light-emitting element, and a blue light-emitting element. The first pad group 611 with which the red light-emitting element is connected may be connected with an auxiliary second power line. The first pad groups 611 with which the green light-emitting element and the blue light-emitting element are connected are connected with an auxiliary first power line. In the second wire group 3, the first power line and the second power line are used for providing power for the light-emitting elements. The ground line is used for provide a ground voltage signal for the driving element. The transfer line is used for providing address data for the driving element. The data line is use for providing data information for the driving element.

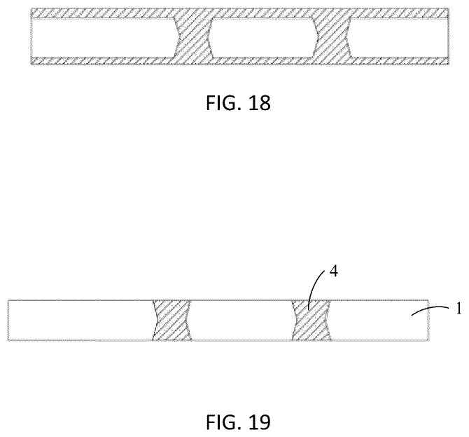

An embodiment of the present application further provides a manufacturing method for a wiring substrate, including following steps.
Step S101: Providing a transparent substrate 1, and forming connecting through holes 11 on the transparent substrate 1, as shown in FIGS. 16 and 17. A diameter of the connecting through hole 11 may be about 0.2 mm, and the connecting through hole 11 may be formed by a laser drilling technology. Laser drilling is to use high power density laser beam to irradiate a material to be processed, so that the material can be quickly heated to a vaporization temperature. Evaporation forms holes. Laser drilling technology has advantages of high speed, high efficiency, good economic benefits and wide application fields. In addition, before the connecting through holes 11 are formed on the transparent substrate 1, a first buffer layer 81 and a second buffer layer 82 may also be formed on a first surface and a second surface of the transparent substrate 1 respectively.
Step S102: Forming connecting part 4 in the connecting through holes 11 of the transparent substrate 1 by filling. Metal can be deposited on both sides of the transparent substrate 1 through a double-sided electroplating process. Then the metal on the first surface and the second surface is removed through annealing and CMP chemical mechanical polishing process. The remaining metal filled in the connecting through holes 11 forms the connecting parts 4, to avoid influence on the subsequent film layer process. As shown in FIG. 18 and FIG. 19, a material of the connecting parts 4 may be copper or another metal.
Step S103: Depositing metal layers on the first surface and the second surface of the transparent substrate 1 respectively, and performing patterning processing, to form a plurality of first-type wires 21 and a plurality of second-type wires 31. A material of the first-type wires 21 and the second-type wires 31 may be copper. The first-type wires 21 may be formed by stacking at least two layers.
Step S104: Forming a first insulating layer 5 is on a side of the plurality of first-type wires 21 away from the transparent substrate 1, and forming a third insulating layer 9 on a side of the plurality of second-type wires 31 away from the transparent substrate 1. In particular, the first insulating layer 5 may include a plurality of layers, for example, includes an inorganic insulating layer, an organic insulating layer and an inorganic insulating layer sequentially stacked.
Step S105: Forming a bonding metal layer 6 on a side of the first insulating layer 5 away from the transparent substrate 1, performing patterning processing on the bonding metal layer 6, to form pad parts 61 distributed in an array, and connecting wires 62 and a third-type wire connected with the pad parts 61. The connecting wire and the third-type wire are connected with the first-type wire 21 through the through hole in the first insulating layer 5.
Step S106: Forming a second insulating layer 7 on a side of the bonding metal layer 6 away from the first insulating layer 5, and performing patterning processing on the second insulating layer 7, to form bonding hole groups corresponding to the pad parts 61. The second insulating layer 7 may include a plurality of layers, for example, includes an inorganic insulating layer, an organic insulating layer and an inorganic insulating layer sequentially stacked.

An embodiment of the present application further provides a tiled screen, including at least two transparent display substrates provided by the above technical scheme.

In the tiled screen provided in the above embodiment, at least two transparent display substrates can be arranged and spliced along the second direction F2. Due to narrow bezel design of the transparent display substrate, the two transparent display substrates are spliced to achieve uniform wiring, eliminating the effect of visually uneven grid feeling in the dark state.

Apparently, those skilled in the art can make various modifications and variations to embodiments of the present disclosure without departing from the spirit and scope of embodiments of the present disclosure. In this way, if the modifications and variations of embodiments of the present disclosure fall within the scope of the claims of the present disclosure and their equivalent technologies, the present disclosure is also intended to include these modifications and variations.

1. A wiring substrate, comprising:
a transparent substrate, comprising a first surface and a second surface opposite to each other, wherein the second surface comprises a wiring region and a bonding region arranged along a first direction, and a plurality of connecting through holes are arranged in the wiring region;
a plurality of first-type wires, located on the first surface of the transparent substrate and in one-to-one correspondence with the plurality of connecting through holes, wherein the plurality of first-type wires are arranged at intervals along the first direction, each of the plurality of first-type wires extends along a second direction, and the first direction is perpendicular to the second direction; and
a plurality of second-type wires, located on the second surface of the transparent substrate and in one-to-one correspondence with the plurality of first-type wires, wherein the plurality of second-type wires are arranged at intervals along the second direction, each of the plurality of second-type wires extends along the first direction, and each of the first-type wires is connected with a corresponding one of the second-type wires at a corresponding one of the connecting though holes.

2. The wiring substrate according to claim 1, wherein the plurality of first-type wires are sequentially divided into M first wire groups along the first direction, a quantity of the first-type wires in each of the first wire groups is p, and M and p are integers greater than 0;
the plurality of second-type wires are sequentially divided into M second wire groups along the second direction, the M second wire groups are in one-to-one correspondence with the M first wire groups, a quantity of the second-type wires in each of the second wire groups is p, and p first-type wires in each of the first wire groups are connected with p second-type wires in a corresponding one of the second wire groups in one-to-one correspondence.

3. The wiring substrate according to claim 2, wherein a distance between every adjacent two of the first wire groups is equal, and a distance between every adjacent two of the first-type wires in each of the first wire groups is equal;
a distance between every adjacent two of the second wire groups is equal, and a distance between every adjacent two of the second-type wires in each of the second wire groups is equal.

4. The wiring substrate according to claim 2, wherein along the second direction, a distance between any adjacent two of the second-type wires in an i^{th} second wire group is a first preset distance, i is an integer greater than 1 and less than M; a distance between any adjacent two of the second-type wires in a 1^{st} second wire group is a second preset distance, and a distance between any adjacent two of the second-type wires in an M^{th} second wire group is a third preset distance;
the second preset distance and/or the third preset distance is less than the first preset distance.

5. The wiring substrate according to claim 2, wherein the plurality of connecting through holes corresponding to the plurality of first-type wires in each of the first wire groups are sequentially arranged along a third direction, the third direction has an included angle with the first direction and/or the second direction.

6. The wiring substrate according to claim 1, further comprising a plurality of connecting parts, wherein the plurality of connecting parts are filled in the plurality of connecting through holes in one-to-one correspondence, and the first-type wires are connected with the second-type wires through the connecting parts in the connecting through holes.

7. The wiring substrate according to claim 2, further comprising a first insulating layer, a bonding metal layer and a second insulating layer;
wherein the first insulating layer is at a side of the plurality of first-type wires away from the transparent substrate;
the bonding metal layer is at a side of the insulating layer away from the transparent substrate, the bonding metal layer comprises a plurality of pad parts arranged at intervals in an array, and the plurality of pad parts are arranged in M rows along the first direction and arranged in M columns along the second direction;
the second insulating layer is at a side of the bonding metal layer away from the first insulating layer, the second insulating layer comprises bonding hole groups in one-to-one correspondence with the plurality of pad parts;
wherein a distance between centers of every adjacent two of the pad parts along the second direction is equal;
each row of the pad parts is opposite to a position of a corresponding one of the first wire groups, and each column of the pad parts is opposite to a position of a corresponding one of the second wire groups.

8. The wiring substrate according to claim 7, wherein along the second direction, an orthographic projection of a j^{th} column of the pad parts on the transparent substrate and an orthographic projection of the second wire group corresponding to the j^{th} column of the pad parts on the transparent substrate have a first relative positional relationship, wherein j is an integer greater than 1 and less than M; an orthographic projection of a first column of the pad parts on the transparent substrate and an orthographic projection of the second wire group corresponding to the first column of the pad parts on the transparent substrate have a second relative positional relationship; an orthographic projection of an M^{th} column of the pad parts on the transparent substrate and an orthographic projection of the second wire group corresponding to the M^{th} column of the pad parts on the transparent substrate have a third relative positional relationship, the first relative positional relationship is different from the second relative positional relationship, and/or the first relative positional relationship is different from the third relative positional relationship.

9. The wiring substrate according to claim 8, wherein the p second-type wires in the second wire group comprise a first power line, a second power line, a ground line, a data line and a transfer line sequentially arranged along the second direction;
the pad part comprises a plurality of first pad groups and a second pad group arranged at intervals along the second direction, the plurality of first pad groups are arranged at intervals along the first direction;
in the j^{th} column of the pad parts, an orthographic projection of the plurality of first pad groups on the transparent substrate is between an orthographic projection of the second power line on the transparent substrate and an orthographic projection of the ground line on the transparent substrate;
in the first column of the pad parts, an orthographic projection of the plurality of first pad groups on the transparent substrate and an orthographic projection of the second power line on the transparent substrate overlap;
in the M^{th} column of the pad parts, an orthographic projection of the plurality of first pad groups on the transparent substrate and an orthographic projection of the ground line on the transparent substrate overlap.

10. The wiring substrate according to claim 9, wherein an orthographic projection of each row of the pad parts on the transparent substrate is within an orthographic projection of the corresponding one of the first-type wires on the transparent substrate.

11. The wiring substrate according to claim 10, wherein along the first direction, one first-type wire in middle of the first-type wires in each of the first wire groups is a middle signal line; the orthographic projection of each row of the pad parts on the transparent substrate is within an orthographic projection of the middle signal line on the transparent substrate.

12. The wiring substrate according to claim 10, wherein the p first-type wires in the first wire group comprise an auxiliary transfer line, an auxiliary data line, an auxiliary ground line, an auxiliary second power line and an auxiliary first power line sequentially arranged along the first direction;
each of the first pad groups comprises a first light-emitting pad and a second light-emitting pad arranged along the second direction, a part of first light-emitting pads in the plurality of first pad groups are connected with the auxiliary first power line and the other part of the first light-emitting pads are connected with the auxiliary second power line;
the second pad group comprises a first column of pads and a second column of pads arranged along the second direction, the first column of pads comprises a plurality of connecting pads connected with the second light-emitting pads in the plurality of first pad groups in one-to-one correspondence, the second column of pads comprises a data signal pad, an address signal pad and a ground pad sequentially arranged, the data signal pad is connected with the auxiliary data line, and the ground pad is connected with the auxiliary ground line;
an orthographic projection of the pad part on the transparent substrate is within an orthographic projection of the auxiliary ground line on the transparent substrate.

13. The wiring substrate according to claim 10, wherein the bonding metal layer further comprises M addressing signal lines extending along the first direction, the M addressing signal lines are in one-to-one correspondence with the M columns of pad parts, each of the addressing signal lines is connected with address signal pads of all of the pad parts of a corresponding column, and the M addressing signal lines are connected with M auxiliary transfer lines in one-to-one correspondence.

14. The wiring substrate according to claim 13, wherein an orthographic projection of the addressing signal line on the transparent substrate is within an orthographic projection of the second-type wire on the transparent substrate.

15. A transparent display substrate, comprising the wiring substrate according to claim 1, and further comprising a plurality of element groups;
wherein the plurality of element groups are in one-to-one correspondence with the plurality of pad parts on the wiring substrate, each of the element groups is connected with a corresponding one of the pad parts through a bonding hole group on the wiring substrate.

16. A tiled screen, comprising at least two transparent display substrates each according to claim 15.
